(19) United States
(12) Patent Application Publication
(10) Pub. No.: US 2024/0188256 A1
(43) Pub. Date: Jun. 6, 2024

(54) CONTAINER DATA CENTER AND REFRIGERATION CONTROL METHOD THEREOF

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/520,032

(22) Filed: Nov. 27, 2023

(30) Foreign Application Priority Data
Dec. 2, 2022 (CN) 202211540525.5

(51) Int. Cl. H05K 7/20; F25B 49/02

(52) U.S. Cl. CPC H05K 7/20827; F25B 49/022; H05K 7/20309; H05K 7/20318; H05K 7/20327; H05K 7/20354; F25B 2600/0251; F25B 2600/13; F25B 2600/2519; F25B 2700/2106

(57) ABSTRACT

The present disclosure discloses a container data center and a refrigeration control method thereof. The container data center at least includes a box body, a server unit and a refrigeration device, where the box body is internally provided with an accommodating space. The server unit is installed in the accommodating space, and a reserved space is reserved between two sides and a top of the server unit and an inner wall of the box body. The refrigeration device includes an indoor unit and an outdoor unit, where the indoor unit is installed in the reserved space, and the indoor unit is positioned above the server unit to divide the reserved space into a cold runner and a hot runner.

### CROSS-REFERENCE TO RELATED APPLICATION

This application claims priority to Chinese Patent Application No. 202211540525.5, titled “CONTAINER DATA CENTER AND REFRIGERATION CONTROL METHOD THEREOF” and filed to the China National Intellectual Property Administration on Dec. 2, 2022, the entire contents of which are incorporated herein by reference.

### TECHNICAL FIELD

The present disclosure relates to the field of data centers, and more particularly, to a container data center and a refrigeration control method thereof.

### BACKGROUND

At present, a refrigeration system of a container data room uses inter-row air conditioners to supply and return air, where inter-row air conditioners are installed inside the container, and the inter-row air conditioners and server cabinets are arranged side by side, which results in decrease of number of IT cabinets in the data room due to the arrangement of the inter-row air conditioners, and thus corresponding computing capacity may also be reduced.

### SUMMARY

An objective of the present disclosure is to provide a container data center and a refrigeration control method thereof, which can arrange more server cabinets and increase computing capacity.

To achieve the above objective, one aspect of the present disclosure provides a container data center, which at least includes a box body, a server unit and a refrigeration device, where the box body is internally provided with an accommodating space. The server unit is installed in the accommodating space, and a reserved space is reserved between two sides and a top of the server unit and an inner wall of the box body. The refrigeration device includes an indoor unit and an outdoor unit, where the indoor unit is installed in the reserved space, and the indoor unit is positioned above the server unit to divide the reserved space into a cold runner and a hot runner.

To achieve the above objective, another aspect of the present disclosure also provides a container data center, which at least includes a box body, an evaporator, a compressor, a condenser, an expansion valve and a fluorine pump, where the evaporator is positioned in the box body, and a temperature sensor is arranged on an outer side of the box body. The evaporator, a first on-off valve, the compressor, the condenser, the expansion valve and the fluorine pump are connected in series with each other to form a refrigeration circuit. The refrigeration circuit is further connected in series with a first passage, where the first passage is connected in parallel with the compressor and the first on-off valve, and a second on-off valve is connected in series with the first passage. The refrigeration circuit is further connected in series with a second passage, where the second passage and the fluorine pump are connected in parallel with each other, and a third on-off valve is connected in series with the second passage.

To achieve the above objective, another aspect of the present disclosure also provides a refrigeration control method for a container data center, where the method is applied to the above container data center. The method includes: obtaining a temperature at an outer side of the box body by means of the temperature sensor, and determining whether the temperature at the outer side of the box body is higher than a predetermined temperature; turning on the compressor, the first on-off valve and the third on-off valve and turning off the fluorine pump and the second on-off valve when the temperature at the outer side of the box body is higher than the predetermined temperature; and turning on the fluorine pump and the second on-off valve and turning off the compressor, the first on-off valve and the third on-off valve when the temperature at the outer side of the box body is lower than or equal to the predetermined temperature.

As can be seen, according to the technical solutions provided by the present disclosure, the server unit may be installed in the accommodating space of the box body of the container, the reserved space is reserved between the two sides and the top of the server unit and the inner wall of the box body, and the indoor unit is positioned above the server unit to divide the reserved space into the cold runner and the hot runner. In this way, the indoor unit is installed above the server unit, which can effectively utilize the space of the container for arranging server cabinets, such that more server cabinets can be arranged to increase the computing capacity. Furthermore, the indoor unit can supply cold air downward from one side, and recover and refrigerate hot air formed after heat exchange from the other side. By using principles of sinking of the cold air and rising of the hot air, compared with arrangement of inter-row air conditioners, air distribution can be improved, ensuring interaction between the cold air and the hot air in a cold channel to be more uniform, avoiding unbalanced heat exchange, effectively refrigerating the server unit, and thus improving refrigeration effects.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic top view of a container data center according to an embodiment of the present disclosure;

FIG. 2 is an A-A schematic sectional view of FIG. 1;

FIG. 3 is a B-B schematic sectional view of FIG. 1; and

FIG. 4 is a schematic diagram of a refrigeration circuit of the container data center according to an embodiment of the present disclosure.

Reference numerals in the drawings: box body 1; accommodating space 11; cushion space 12; server unit 2; indoor unit 31; evaporator 311; outdoor unit 32; compressor 321; condenser 322; expansion valve 323; fluorine pump 324; first on-off valve 33; first passage 34; second on-off valve 35; second passage 36; third on-off valve 37; reserved space 4; cold runner 41; and hot runner 42.

### DETAILED DESCRIPTION

Detailed description of implementations of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

At present, a refrigeration system of a container data room uses inter-row air conditioners to supply and return air, where inter-row air conditioners are installed inside the container, and the inter-row air conditioners and server cabinets are arranged side by side, which results in decrease of number of IT cabinets in the data room due to the arrangement of the inter-row air conditioners, and thus corresponding computing capacity may also be reduced.

Furthermore, because the existing inter-row air conditioners and the server cabinets are placed side by side, it is easy to form an air flow short circuit in the container in the process of circulation and heat exchange, resulting in uneven hot and cold in local space and thus adversely affecting normal operation of an IT device.

Therefore, based on the above problems, a container data center and a refrigeration control method thereof are urgently needed, such that more server cabinets may be arranged to increase computing capacity and improve heat dissipation effects on the server cabinets.

The technical solutions in the embodiments of the present disclosure will be clearly and completely described with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

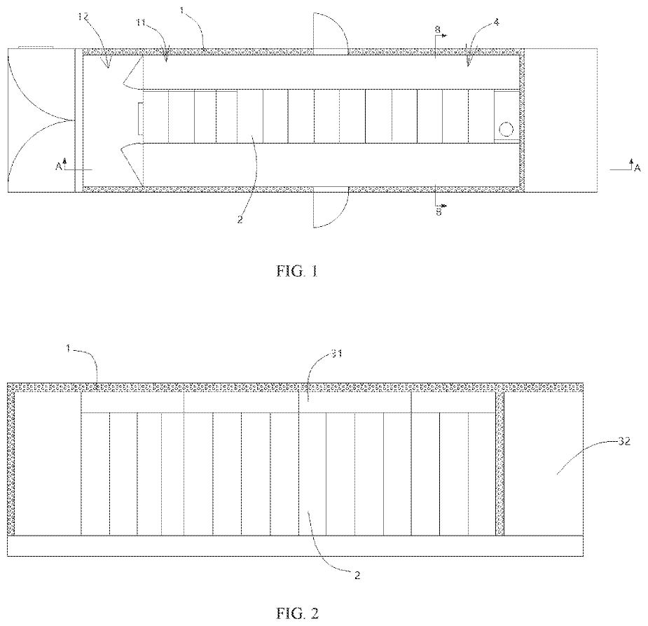

As shown in FIGS. 1 to 3, in an implementable embodiment, a container data center may at least include a box body 1, a server unit 2 and a refrigeration device, where the box body 1 is internally provided with an accommodating space 11. The server unit 2 may be installed in the accommodating space 11, and a reserved space 4 is reserved between two sides and a top of the server unit 2 and an inner wall of the box body 1. It should be noted that the server unit 2 may be arranged in parallel along a length direction of the box body 1, and the server unit 2 may be arranged on a symmetrical center line of the box body 1, such that the reserved space 4 between the left and right sides of the server unit 2 and the inner wall of the box body 1 is the same, and of course, the server unit 2 may also be arranged off-center, which is not specifically limited in the present disclosure.

In actual use, the server unit 2 may comprise a plurality of server cabinets arranged in a straight line. Of course, the server unit 2 may also include an uninterrupted power supply (UPS) and a battery for supplying power to the server cabinets, and a control cabinet, etc.

The refrigeration device may include an indoor unit 31 and an outdoor unit 32. The indoor unit 31 may be installed in the reserved space 4 to perform heat dissipation on the server unit 2. The outdoor unit 32 may be installed on an outer side of the box body 1, such that noises can be reduced and refrigeration effects can be ensured.

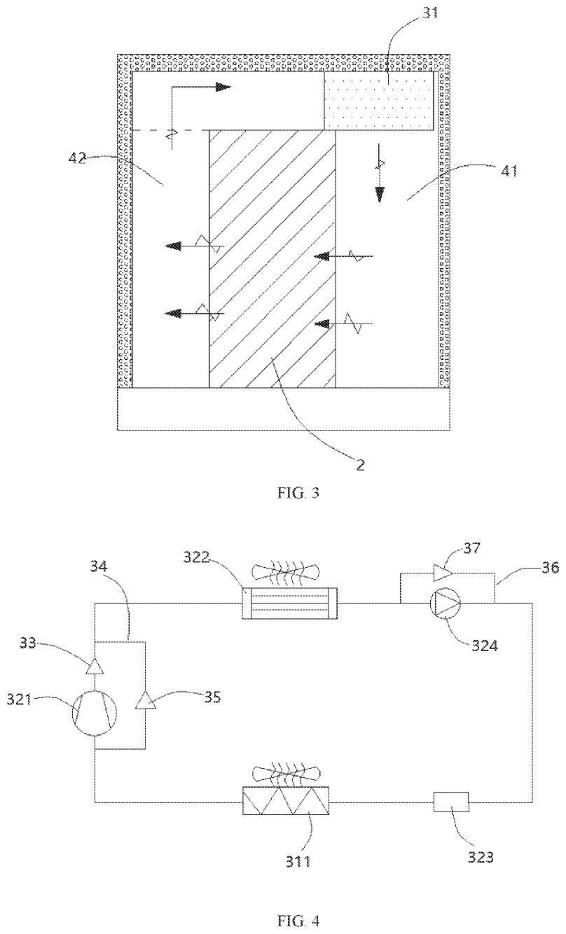

In an implementable embodiment, referring to FIG. 3, the indoor unit 31 may be positioned above the server unit 2, thereby dividing the reserved space 4 into a cold runner 41 and a hot runner 42. In this way, the indoor unit can supply cold air from one side, return air from the other side, blow the air downward from the top. Compared with arrangement of inter-row air conditioners, air distribution can be improved, ensuring interaction between the cold air and the hot air in a cold channel to be more uniform, avoiding unbalanced heat exchange, effectively refrigerating the server unit, and thus improving the refrigeration effects.

Further, an air outlet of the indoor unit 31 should be positioned directly above the cold runner 41, such that the cold air can directly flow downwards, thus avoiding loss of the cold air in the passage and ensuring the heat dissipation effects to the server unit.

In actual use. a plurality of indoor units 31 may be provided, and the plurality of indoor units 31 are arranged in a length direction of the server unit 2. Specific number of the indoor units 31 may be set according to requirements, and the plurality of indoor units 31 may be arranged according to heat dissipation requirements of the server unit 2. For example, arrangement of the indoor units 31 may be reduced at the UPS and the battery because of lower heat dissipation requirements. In contrast, the number of the indoor units 31 may be increased at the server cabinet.

In an implementable embodiment, referring to FIG. 4, the indoor unit 31 includes an evaporator 311. Of course, a fan and a coil or the like may be provided in the indoor Unit 31 to accelerate air motion. The outdoor unit 32 includes a compressor 321, a condenser 322, and an expansion valve 323. The evaporator 311, the compressor 321, the condenser 322 and the expansion valve 323 are connected in series to form a refrigeration circuit, thereby forming a refrigeration cycle. It should be noted that the evaporator 311, the compressor 321, the condenser 322 and the expansion valve 323 are four major refrigeration components, reference may be made to the prior art for their specific structures, which are not to be described in detail here.

Further, the outdoor unit 32 may also include a fluorine pump 324, which is connected in series in the refrigeration circuit. Furthermore, a first on-off valve 33 is connected to an outlet of the compressor 321. The refrigeration circuit is further connected in series with a first passage 34, where the first passage 34 is connected in parallel with the compressor 321 and the first on-off valve 33, and a second on-off valve 35 is connected in series with the first passage 34. The refrigeration circuit is further connected in series with a second passage 36, where the second passage 36 and the fluorine pump 324 are connected in parallel with each other, and a third on-off valve 37 is connected in series with the second passage 36.

It should be noted that the first passage 34 and the second passage 36 may be pipelines or pipes. The outer side of the box body 1 should also be provided with a temperature sensor for detecting an outdoor ambient temperature.

In actual use, the refrigeration control method for the container data center may include: obtaining, by a controller, a temperature at the outer side of the box body 1 by means of the temperature sensor, and determining whether the temperature at the outer side of the box body 1 is higher than a predetermined temperature. When the temperature at the outer side of the box body 1 is higher than the predetermined temperature, the compressor 321, the first on-off valve 33 and the third on-off valve 37 are turned on, and the fluorine pump 324 and the second on-off valve 35 are turned off. In this case, the fluorine pump 324 is short-circuited by the second passage 36, such that the fluorine pump 324 does not participate in operation, and the compressor 321 is employed for compression refrigeration. When the temperature at the outer side of the box body 1 is lower than or equal to the predetermined temperature, this indicates that the external environment may be used for heat dissipation of the box body 1. In this case, the fluorine pump 324 and the second on-off valve 35 may be turned on, and the compressor 321, the first on-off valve 33 and the third on-off valve 37 may be turned off. In this case, the fluorine pump 324 is operating, but the compressor 321 is short-circuited by the first passage 34.

It should be pointed out that the predetermined temperature is set by technicians according to technical experiences, which may be 15° C., 10° C., and so on.

In an implementable embodiment, the box body 1 is also internally provided with a cushion space 12. The cushion space 12 is communicated with the accommodating space 11 through a switch gate. In this way, a cushion area may be provided to prevent people from entering the box body 1 and prevent external dusts from entering the accommodating space.

Based on the same inventive concept, the present disclosure also provides a container data center, which at least includes a box body 1, an evaporator 311, a compressor 321, a condenser 322, an expansion valve 323 and a fluorine pump 324, where the evaporator 311 is positioned in the box body 1, and a temperature sensor is arranged on the outer side of the box body 1. The evaporator 311, the compressor 321, the condenser 322, the expansion valve 323 and the fluorine pump 324 are connected in series with each other to form a refrigeration circuit. The refrigeration circuit is further connected in series with a first passage 34, where the first passage 34 is connected in parallel with the compressor 321 and the first on-off valve 33, and a second on-off valve 35 is connected in series with the first passage 34. The refrigeration circuit is further connected in series with a second passage 36, where the second passage 36 and the fluorine pump 324 are connected in parallel with each other, and a third on-off valve 37 is connected in series with the second passage 36.

Reference may be made to the above contents for specific structures and principles of the refrigeration circuit, which are not to be described in detail here.

As can be seen, according to the technical solutions provided by the present disclosure, the server unit may be installed in the accommodating space of the box body of the container, the reserved space is reserved between the two sides and the top of the server unit and the inner wall of the box body, and the indoor unit is positioned above the server unit to divide the reserved space into the cold runner and the hot runner. In this way, the indoor unit is installed above the server unit, which can effectively utilize the space of the container for arranging server cabinets, such that more server cabinets can be arranged to increase the computing capacity. Furthermore, the indoor unit can supply cold air downward from one side, and recover and refrigerate hot air formed after heat exchange from the other side. By using principles of sinking of the cold air and rising of the hot air, compared with arrangement of inter-row air conditioners, air distribution can be improved, ensuring interaction between the cold air and the hot air in a cold channel to be more uniform, avoiding unbalanced heat exchange, effectively refrigerating the server unit, and thus improving refrigeration effects.

Further, in the present disclosure, the server unit and the refrigeration system are integrated in the container, which can realize productization of the data room, making it convenient and quick to move and install the container.

Further, two operation modes (i.e., the compressor and the fluorine pump) may be used in the refrigeration circuit, and the corresponding operation mode may be selected according to the external ambient temperature. Outdoor low-temperature air may be indirectly used as a cold source to save refrigeration energy consumption.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A container data center at least comprising a box body (1), a server unit (2) and a refrigeration device, wherein the box body (1) is internally provided with an accommodating space (11);
the server unit (2) is installed in the accommodating space (11), and a reserved space (4) is reserved between two sides and a top of the server unit (2) and an inner wall of the box body (1);
the refrigeration device comprises an indoor unit (31) and an outdoor unit (32); and
the indoor unit (31) is installed in the reserved space (4), and the indoor unit (31) is positioned above the server unit (2) to divide the reserved space (4) into a cold runner (41) and a hot runner (42).

2. The container data center according to claim 1, wherein an air outlet of the indoor unit (31) is positioned directly above the cold runner (41).

3. The container data center according to claim 2, wherein a plurality of the indoor units (31) are provided, and the plurality of indoor units (31) are arranged along a length direction of the server unit (2).

4. The container data center according to claim 3, wherein the indoor unit (31) comprises an evaporator (311);
the outdoor unit (32) comprises a compressor (321), a condenser (322), and an expansion valve (323); and
the evaporator (311), the compressor (321), the condenser (322) and the expansion valve (323) are connected in series to form a refrigeration circuit.

5. The container data center according to claim 4, wherein the outdoor unit (32) further comprises a fluorine pump (324), and the fluorine pump (324) is connected in series in the refrigeration circuit;
an outlet of the compressor (321) is connected to a first on-off valve (33);
the refrigeration circuit is further connected in series with a first passage (34), the first passage (34) is connected in parallel with the compressor (321) and the first on-off valve (33), and a second on-off valve (35) is connected in series with the first passage (34); and
the refrigeration circuit is further connected in series with a second passage (36), the second passage (36) and the fluorine pump (324) are connected in parallel with each other, and a third on-off valve (37) is connected in series with the second passage (36).

6. The container data center according to claim 5, wherein a temperature sensor is arranged on an outer side of the box body (1).

7. The container data center according to claim 1, wherein a cushion space (12) is further provided in the box body (1); and
the cushion space (12) is communicated with the accommodating space (11) through a switch gate.

8. A container data center at least comprising a box body (1), an evaporator (311), a compressor (321), a condenser (322), an expansion valve (323) and a fluorine pump (324), wherein the evaporator (311) is positioned in the box body (1);
a temperature sensor is arranged on an outer side of the box body (1);
the evaporator (311), a first on-off valve (33), the compressor (321), the condenser (322), the expansion valve (323) and the fluorine pump (324) are connected in series with each other to form a refrigeration circuit;
the refrigeration circuit is further connected in series with a first passage (34), the first passage (34) is connected in parallel with the compressor (321) and the first on-off valve (33), and a second on-off valve (35) is connected in series with the first passage (34); and
the refrigeration circuit is further connected in series with a second passage (36), the second passage (36) and the fluorine pump (324) are connected in parallel with each other, and a third on-off valve (37) is connected in series with the second passage (36).

9. A refrigeration control method for a container data center, the method being applied to a container data center at least comprising a box body (1), an evaporator (311), a compressor (321), a condenser (322), an expansion valve (323) and a fluorine pump (324), wherein the evaporator (311) is positioned in the box body (1);
a temperature sensor is arranged on an outer side of the box body (1);
the evaporator (311), a first on-off valve (33), the compressor (321), the condenser (322), the expansion valve (323) and the fluorine pump (324) are connected in series with each other to form a refrigeration circuit;
the refrigeration circuit is further connected in series with a first passage (34), the first passage (34) is connected in parallel with the compressor (321) and the first on-off valve (33), and a second on-off valve (35) is connected in series with the first passage (34); and
the refrigeration circuit is further connected in series with a second passage (36), the second passage (36) and the fluorine pump (324) are connected in parallel with each other, and a third on-off valve (37) is connected in series with the second passage (36); and the method comprising:
obtaining a temperature at an outer side of the box body (1) by means of the temperature sensor, and determining whether the temperature at the outer side of the box body (1) is higher than a predetermined temperature; and
turning on the compressor (321), the first on-off valve (33) and the third on-off valve (37) and turning off the fluorine pump (324) and the second on-off valve (35) when the temperature at the outer side of the box body (1) is higher than the predetermined temperature.

10. The refrigeration control method for the container data center according to claim 9, wherein the fluorine pump (324) and the second on-off valve (35) are turned on, and the compressor (321), the first on-off valve (33) and the third on-off valve (37) are turned off when the temperature at the outer side of the box body (1) is lower than or equal to the predetermined temperature.
